(19) United States
(12) Patent Application Publication
(10) Pub. No.: US 2009/0308020 A1
(43) Pub. Date: Dec. 17, 2009

(54) ENERGY CONVERSION SYSTEM

(75) Inventor: Michael David Duke, Hamilton (NZ)

Correspondence Address: KREMBLAS, FOSTER, PHILLIPS & POLLICK, 7632 SLATE RIDGE BOULEVARD, REYNOLDSBURG, OH, 43068, US

(73) Assignees: Michael David Duke; Waikatolink Limited, Hamilton (NZ)

(21) Appl. No.: 12/297,471

(22) PCT Filed: Apr. 19, 2007
(86) PCT No.: PCT/NZ2007/000090

§ 371 Date: Mar. 9, 2009

(30) Foreign Application Priority Data
Apr. 19, 2006 (NZ) 546718

(51) Int. Cl. E04D 13/18; H01L 31/042

(52) U.S. Cl. 52/745.2; 136/244

(57) ABSTRACT

The present invention relates to an energy conversion device including a roofing material having one or more open channels and one or more photovoltaic modules, characterised in that the one or more photovoltaic modules is bonded directly or indirectly to the roofing material so as to form one or more covered channels through which fluid can flow. In this manner an energy conversion device may be formed in a standard roofing material combining the benefits of Photovoltaic modules to generate electricity and a solar thermal collector to provide heat from the Sun in a single integrated device.

### TECHNICAL FIELD

This invention relates to an energy conversion device.

### BACKGROUND ART

Solar thermal collectors and photovoltaic cells are well established technologies for converting solar energy into other useful forms of energy. The solar thermal collector is typically a simple device which uses radiation from the sun to heat a fluid which is subsequently passed through a heat exchanger to remove heat from the fluid for other uses.

The central component of a solar heating system is the collector. A flat plate solar collector, the most common type, is made up of a selectively layered absorber that absorbs the incoming solar radiation and transforms it into heat. This absorber is commonly embedded in a thermally insulated box with a transparent cover to minimise thermal loss. A heat conducting fluid (usually a mixture of water and non-environmentally damaging antifreeze) flows through the absorber and circulates between the collector and the heat exchanger or warm water storage tank. Solar thermal systems can achieve efficiencies in excess of 75%.

Another well established form of converting solar energy involves photovoltaic (PV) cells. PV cell systems convert solar radiation directly into DC electricity. The DC electricity may be used directly or converted into AC, for example with an inverter, and then supplied to a building to provide power. Any excess electricity may be exported to the grid where it is sold.

PV solar cells are typically made from thin wafers of silicon. The wafers are generally configured and encapsulated to provide robust products, called photovoltaic modules (PV modules), with a typical service lifetime exceeding twenty years. Solar PV modules have typical efficiency of around 16%. There is very little degradation in solar PV module performance over their service lifetime and, apart from a recommended once a year clean, they are practically maintenance free.

There are, however, a number of disadvantages currently experienced with application of these technologies.

Solar thermal collectors typically require pipes or channels in the absorber to contain the heat conducting fluid. If pipes are used these generally need to be bonded to the absorber to provide good thermal transfer from the absorber to the fluid. This adds to the time and cost of forming a collector, and may also be a limiting factor (due to the potential failure of the bonding of the pipes) on the efficiency and lifetime of a collector.

Alternatively, forming channels in the absorber requires additional machining (e.g. drilling out a channel) or in some cases forming the absorber in parts which are subsequently assembled such that a channel is formed between the parts. This also requires additional machining and assembly, thus adding to the cost of forming a collector.

Solar thermal collectors tend to have large collectors in order to capture and provide a useful amount of heat. Their size and weight means they assume the nature of a significant building structure in their own right.

In a typical installation on a roof of a building, the solar thermal collector is mounted in a frame including structural members to support the weight of the collector and to provide structural connection to the roof and to the building. Installation is relatively expensive as it requires the erection of a framework and its attachment to the building, and the appropriate connections for the fluid circuit. This adds to the expense of the installation and may also create delays as a number of people may be needed to provide the range of skills (carpentry, plumbing etc) required to complete the installation.

Furthermore the installation of the solar thermal collector typically requires some modification to the roof, including joins, to accommodate attachment of the support frame and connection of the fluid circuit. These modifications increase the likelihood of subsequent failure of joins, leading to leakage through the roof.

The added weight of the solar thermal collector may also give rise to engineering concerns regarding the ability of the structure to support the device. This applies particularly to the common situation where the solar thermal collector is retrofitted to an existing building.

Similar disadvantages apply to installations of PV systems in that their installation requires a frame for the PV cells and a support frame to attach the unit to the building. In this instance as well as carpenters and plumbers, an electrician is required to make the necessary electrical connections.

Hence installation of both systems onto an existing building can lead to problems with additional weight loading onto the structure, and the introduction of potential leakage sites through the roof. Depending on the aspect of the frame holding the solar thermal connector or PV panel, there is the added issue of increased wind loading due to the pressure of wind against the panel and the support framework. All these issues may potentially lead to higher insurance costs due to the increased risk of damage to the structure.

Generally speaking, the addition of solar thermal collectors and/or photovoltaic panels to an existing roof line may also result in an unsightly appearance.

In recent times there is a growing awareness of the need to make use of renewable energy sources and techniques. In some parts of the world, local authorities are requiring a level of energy self sufficiency for all new buildings or renovations of buildings within their jurisdiction. Use of solar thermal panels and PV systems in a manner that overcomes the above disadvantages is therefore a matter of considerable interest.

It is an object of the present invention to address the foregoing problems or at least to provide the public with a useful choice.

All references, including any patents or patent applications cited in this specification are hereby incorporated by reference. No admission is made that any reference constitutes prior art. The discussion of the references states what their authors assert, and the applicants reserve the right to challenge the accuracy and pertinency of the cited documents. It will be clearly understood that, although a number of prior art publications are referred to herein, this reference does not constitute an admission that any of these documents form part of the common general knowledge in the art, in New Zealand or in any other country.

It is acknowledged that the term ‘comprise’ may, under varying jurisdictions, be attributed with either an exclusive or an inclusive meaning. For the purpose of this specification, and unless otherwise noted, the term ‘comprise’ shall have an inclusive meaning—i.e. that it will be taken to mean an inclusion of not only the listed components it directly references, but also other non-specified components or elements. This rationale will also be used when the term ‘comprised’ or ‘comprising’ is used in relation to one or more steps in a method or process. Further aspects and advantages of the present invention will become apparent from the ensuing description which is given by way of example only.

### DISCLOSURE OF INVENTION

According to one aspect of the present invention there is provided an energy conversion device which includes

a roofing material having one or more open channels and
at least one photovoltaic module
characterised in that
the photovoltaic module is bonded directly or indirectly to the roofing material so as to form a covered channel through which fluid can flow.

According to another aspect of the present invention there is provided a method of construction of an energy conversion device including

a roofing material having one or more open channels and
at least one photovoltaic module,
characterised by the step of
bonding the photovoltaic module directly or indirectly onto the roofing material so as to form a covered channel through which fluid can flow.

The energy conversion device is configured to capture energy from the sun and convert it into electricity and useable heat.

In a preferred embodiment the roofing material is a standard roofing product. A standard roofing product is to be understood as a roofing product that is commonly used in the construction industry. Choosing a commonly used roofing product ensures that the basis of the energy conversion device is well known within the construction industry and accepted by it as a preferred method of forming a roof. As a consequence uptake of the present invention may be rapid, as it will be seen as an enhancement of existing technology rather than an entirely new system.

Furthermore, the engineering design issues and the skills required to install the roofing material are already well known within the industry. Therefore the roofing material, as modified to form the energy conversion device, may be readily incorporated into the design of a structure and installed by anyone skilled in the art of using the roofing material.

In a preferred embodiment the roofing material is a long run metal panel. This provides an extended surface on which the energy conversion device may be formed.

Each energy conversion device must be connected to a fluid flow circuit as well as an electrical circuit. Plumbing and electrical connections are expensive to install and maintain. Therefore in practice the number of fluid flow and electrical connections needs to be kept to a minimum. The use of long run roofing sheets increases the area of each device without increasing the number of connections.

Those skilled in the art will appreciate, however, that other forms of roofing material, for example tiles, may be used and that reference to roofing material configured as preformed long run metal sheets only throughout this specification should not be seen as limiting.

Tiles made from a metallic base are another common form of roofing material. An energy conversion device can be constructed from such tiles. However, each tile requires plumbing and electrical connection to the rest of the system. The additional cost of installation and maintenance of a tile based system, due to the large increase in plumbing and electrical connections, makes it less viable from a financial viewpoint, although there may be other reasons for choosing to use tiles, for example to complement the appearance of the rest of a tiled roof.

Preferably the roofing material is made from a material having good thermal conductivity as this enhances the performance of a solar heat collector. Examples of such materials include steel, copper and aluminium, all of which are used as common roofing materials.

Not only do these materials have good thermal conductivity but may also provide other advantages, such as the ability to bond to other materials, including other steel, copper or aluminium substrates respectively.

Furthermore, roofing material made from these materials may be malleable and can be formed into complex shapes, on the site if necessary.

Preferably the roofing material is made from long run steel such as COLORSTEEL, as this is cost effective and is commonly used for roofing in many countries, including New Zealand.

Those skilled in the art will however appreciate that other metals, such as aluminium or copper, may be used and that reference to roofing material made from long run steel only throughout this specification should not be seen as limiting.

In a preferred embodiment the roofing material is configured to include a substantially planar section. The advantage of a planar section is that it provides a flat surface onto which the photovoltaic modules can be bonded. Photovoltaic modules are generally produced in planar form and are easily damaged if deformed by bending. It is possible to bond the photovoltaic modules onto a curved surface but it not as simple as bonding to a flat surface.

In a preferred embodiment the roofing material is configured as a standing seam roof. Standing seam roofs are a common form of long run roofing. They are formed from flat sheets of metal, commonly steel or aluminium, which may be cut or otherwise formed so as to extend from a ridgeline of a roof to the outer edge of the eaves. The longitudinal edges of the sheet are configured to form a ridge on either side of the sheet, such that neighbouring sheets can be overlapped, folded and sealed, forming a seam along the ridge. In typical installations the width of the substantially planar section between adjacent ridges is 5-60 cm, however this should not be seen as limiting.

The substantially flat planar section formed between adjacent ridges is a preferred platform for the configuration of the present invention.

In another embodiment the roofing material is configured as a trough sheet roof. A trough sheet roof is formed from panels configured as substantially parallel crests with substantially planar troughs between adjacent crests. The panels are placed on the roof such that the troughs are aligned along the fall line of the roof.

In the simplest embodiment of the present invention an open channel in the roofing material may be the space between adjacent protrusions on the surface of the roofing material. This could be the space between adjacent ridges in a standing seam roof or between adjacent crests in a trough sheet roof.

A cover may be bonded to adjacent protrusions on the surface of the roofing material in order to create a covered channel through which liquid can flow. In this manner a simple solar thermal collector may be formed, using the high thermal conductivity of the roofing material to provide an effective absorber. Reference to a covered channel throughout this specification should be understood to refer to a watertight space which is enclosed apart from openings to allow fluid to enter or exit the channel. A covered channel may be of any shape, size and configuration.

Heat is removed from the solar heat collector by heat transfer liquid flowing through the covered channels formed between the open channels in the roofing material and the cover.

In a typical arrangement the fluid is in a closed circuit which, as well as the covered channels through the solar collector, includes connections to a heat exchanger which removes heat from the fluid and returns cooler fluid to the circuit.

In practice, however, a solar thermal collector formed as above may have low thermal efficiency, as well as being impractical. The heat transfer from the cover to the liquid is likely to be poor due to the small ratio of the contact area of the cover to the volume of heat transfer liquid in the channel.

In a preferred embodiment one or more open channels are formed in the substantially planar section of the roofing material. The open channels may be formed by a process of folding, rolling or by using a press. However, any method that deforms the metal surface to form an open channel can be used, and reference to folding, rolling or pressing only in this specification should not be seen as limiting.

In a preferred embodiment the cross section of an open channel is rectangular. A rectangular channel may be readily formed in long run metal roofing materials by folding, rolling or pressing. However, any convenient shape may be used.

In other embodiments an open channel may be formed in a curved section of the roofing material. However, as discussed above, bonding a typical photovoltaic cell to a curved surface is generally more difficult than bonding it to a planar surface. Such embodiments are therefore likely to be more expensive as typically some form of intermediary substrate, which has a planar surface for bonding to the photovoltaic module and a curved surface to match the curve of the roofing material, may be required.

In a preferred embodiment the open channel is formed during production of the roofing material. Integrating the manufacture of the open channel(s) with the roof product increases the value of the roofing product by adding multiple features in the same or similar forming process.

It is typically less expensive to form an open channel, or groove, in the surface of a sheet of metal than it is to form a closed channel. The cost may be further reduced if the open channels are formed as an integral part of forming a roofing material.

In a preferred embodiment the open channel extends substantially the length of a roofing panel.

The open channel(s) may be straight or formed into a pattern. For example the open channel may form an open loop extending over substantially the length of the roof panel with the open ends of the loop at the same end of the panel.

An energy conversion device according to the present invention is formed by covering the open channel in a roofing material by directly or indirectly bonding at least one photovoltaic module to the roofing material so as to cover the open channel.

Reference to a photovoltaic module throughout this specification should be understood to refer to an independent, self contained device for converting light energy into electrical energy through the photovoltaic effect.

In most applications the light energy is solar radiation, although other sources of light may be used.

The active component of a typical photovoltaic module is a photovoltaic cell. This is formed from a semi-conducting material, commonly a silicon wafer. In order to protect the fragile wafer and provide a product which can withstand common usage, the wafer is usually incorporated in a photovoltaic module (PV module).

In a typical PV module the wafer is sandwiched between layers of transparent material, such as ethylene vinyl acetate (EVA), which provides support and protection for the wafer. The (upper) surface of the module (ie, the surface to be exposed to the Sun) is typically protected by rigid, transparent sheet of material such as a pane of glass.

A substrate is typically bonded to the opposite (lower) surface of the module. This is often a polyvinyl fluoride sheet, such as Tedlar, that bonds with EVA. Alternatively, the substrate may be a metallic plate that provides strength and stiffness to the PV module.

The above description relates to a typical photovoltaic module. However, it will be understood by those skilled in the art that any PV module may be used in the current invention, and that the description given above is provided for illustration of a typical PV module only and is not intended to be limiting.

In a preferred embodiment the PV module includes a substrate of the same material as the roofing material.

For example a PV module with a steel substrate can be readily bonded to a long run steel roofing material. Not only does this ensure a good bond, but also matches the thermal expansion of the substrate and the roofing material. This is an important feature, as a bond formed between two materials of different thermal conductivity will be stressed during thermal cycling and hence may have a limited lifetime.

The present invention provides a combined solar thermal collector and PV module system that utilises common roofing material. This arrangement has the advantage of providing both facilities without the requirement for separate frames or other support structures. By utilising common roofing material the devices may be readily incorporated into a building without major reconstruction or changes to the appearance of the building.

A further advantage of combining PV module and solar thermal collector devices in this way is that the power output of the PV module (under normal operating conditions) is increased due to the cooling provided by bonding it to the solar thermal collector. Typically the voltage generated by the PV module when bonded to (and cooled by) the solar thermal collector may be more than 10% greater than that when the PV module is operated alone. This provides a significant advantage over operation of stand alone PV modules and solar thermal collectors.

According to another aspect of the present invention there is provided an energy conversion device substantially as described above which includes a convection plate.

Reference to a convection plate throughout this specification should be understood to refer to a sheet of heat conducting material. One function of a convection plate is to act as a collector for a solar thermal collector. Another function of a convection plate is to form a substrate for a PV module or a surface onto which a PV module may be readily bonded.

A convection plate according to the present invention is configured to form bonded joins with a long run roofing panel having one or more open channels so as to form a covered channel through which fluid can flow.

In preferred embodiments the convection plate is formed from the same material as the roofing material. In this way the thermal conductivity of the roofing material and convection plate are the same, thus reducing or eliminating stress on the bond due to mismatch during thermal cycling.

According to another aspect of the present invention there is a method of forming an energy conversion device substantially as described above including the additional steps of
a) bonding the photovoltaic module to a first side of a convection plate, and
b) bonding a second side of the convection plate to the roofing material so as to form a covered channel through which fluid can flow.

According to another aspect of the present invention there is provided a method for producing an energy conversion device substantially as described above including the additional steps of
a) bonding a first side of the convection plate to the roofing material so as to form a covered channel through which fluid can flow, and
b) bonding a photovoltaic module to a second side of the convection plate.

In a preferred embodiment the energy conversion device includes an entrapped air gap above the photovoltaic modules.

In a preferred embodiment the air gap is formed by a sheet of transparent material located in a plane above and substantially parallel to the plane of the photovoltaic module and wherein the edges of the transparent material are sealed to the roofing material.

Solar heating of the entrapped air is used to raise the temperature of the energy conversion device through the greenhouse effect. The increased temperature increases the quantity of heat transferred to the fluid in the channels (for an equivalent flow rate), improving the efficiency of the solar thermal collector component of the energy conversion device.

Preferably the transparent material is glass although other transparent material may be used, for example a plastics material such as UV stabilised polycarbonate.

In an alternate embodiment a honeycomb module material provides the entrapped air gap. A honeycomb module may be any structure that is configured to retain or entrap air in cells.

In a preferred embodiment a layer of insulating material is bonded to the surface of the roofing material opposite that containing the channels (the lower surface). Insulating the lower surface of the roofing material improves the efficiency of the solar thermal collector by limiting heat loss through the roof. It may also reduce heat loading from the roofing material to the inside of the structure during hot periods, such as during summer.

The energy conversion system described above provides many significant advantages over conventional systems by combining PV module technology directly with solar thermal collection as integrated components of a common roofing material.

With the present energy conversion system the solar-electric PV module and the solar thermal collector are installed as part of the normal installation of the roof, rather than as three separate installations (roof, PV module and solar thermal collector). Furthermore, by appropriate arrangement of the electrical and plumbing connections to the energy conversion system it can be readily connected to the electrical and plumbing circuits of the building without the need for further extensive electrical and plumbing work.

In practice it is envisaged that the energy conversion system will be installed by a suitably qualified person who will install the roofing material incorporating the PV modules and solar thermal collector, and make all the necessary connections at the same time, saving time and expense.

Incorporating the PV module and solar thermal collector into the common roofing material as an integral part of the system removes the need for separate structures to support them. The result is a major reduction (over conventional arrangements) in the amount of material used and therefore the additional weight loading on the structure. There is also a significant cost saving over conventional devices in the use of fewer materials and the reduction of labour costs required for construction and installation of support structures.

The manner of forming the solar thermal collector does not interfere with the integrity of the roofing material, and reduces any additional risk of leakage or other failure due to the fixtures required to attach the mounting for a conventional solar thermal collector or PV module system.

The present energy conversion device, being formed as part of the normal roofing structure, will blend in with the roofline, resulting in a more acceptable appearance than is the case with PV systems or solar thermal collectors mounted on frames above the roof. It may also reduce the additional wind loading experienced with conventional installations.

The total cost of the integrated energy conversion system may also be lower than the sum of the separate costs for roofing, solar thermal collector and PV module system, there being no need for separate support structures or additional strengthening of the framework of the building.

Furthermore, the efficiency of the energy conversion device is enhanced by the greater power generated by the PV modules when cooled by the solar thermal collector.

### BRIEF DESCRIPTION OF DRAWINGS

Further aspects of the present invention will become apparent from the following description which is given by way of example only and with reference to the accompanying drawings in which:

FIG. 1 shows a cross-section view of an energy conversion device; and

FIG. 2 shows a cross-section view of an energy conversion device on a standing seam roof; and

FIG. 3 shows a cross-section view of another embodiment of an energy conversion device;

FIG. 4 shows a cross-section view of another embodiment of an energy conversion device; and

FIG. 5 shows a cross-section view of another embodiment of an energy conversion device; and

FIG. 6 shows a cut-away plan view of an energy conversion device.

### BEST MODES FOR CARRYING OUT THE INVENTION

FIG. 1 shows a cross-section view of an energy conversion device (1). A standard roofing material (2) has an open channel (3) formed with a rectangular cross section. The open channel (3) is sealed by bonding a photovoltaic module (4) to the roofing material (2) at the surface (5) of the roofing material (2). The bonding of the photovoltaic module (4) to the roofing material (2) over the open channel (3) is such as to form a rectangular covered channel through which fluid (not shown) can flow while remaining contained within the channel.

With this simple arrangement solar energy is firstly captured and converted into electricity by the photovoltaic module (4) and secondly into heated fluid within the open channels (3). The invention incorporates the known properties of photovoltaic modules together with a solar collector as integral parts of a roofing system.

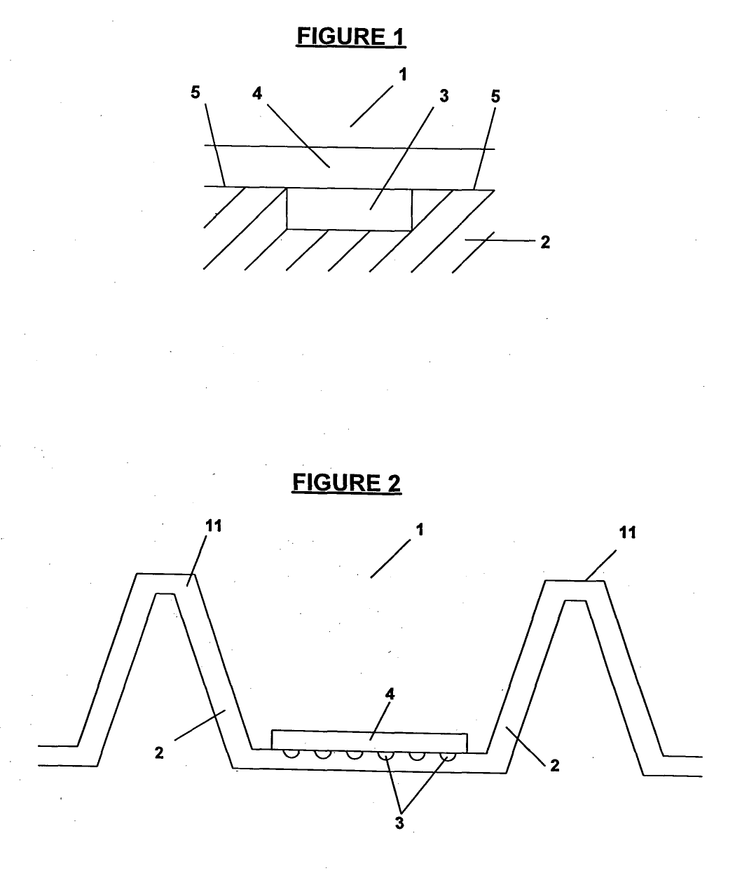

FIG. 2 shows a cross-sectional view of another embodiment of the present invention. In this case one or more open channels (3) having semi circular cross section are formed in the substantially flat section between two ridges (11) of a roofing material (2) formed in a standing seam configuration. One or more photovoltaic modules (4) are bonded to the roofing material (2) over the open channels (3) to form covered channels.

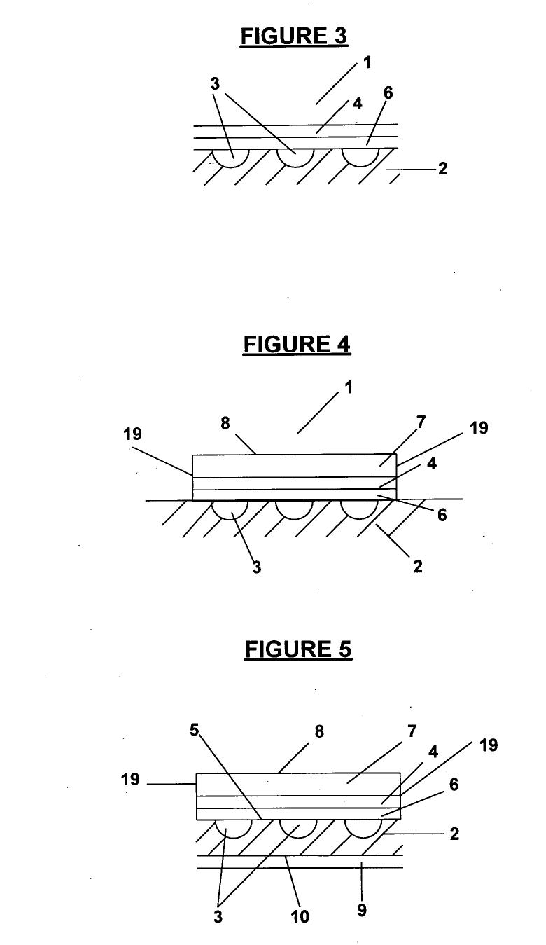

FIG. 3 shows a cross-sectional view of another embodiment of the present invention in which a high thermal conductivity convection plate (6) is bonded between the roofing material (2) and the photovoltaic modules (4). The convection plate (6) is bonded to the roofing material (2) over the open channels (3) so as to form covered channels. The inclusion of a convection plate (6) enhances the thermal contact between the photovoltaic modules (4) and the fluid flowing through the covered channel.

FIG. 4 shows a cross-sectional view of an energy conversion device as described above including a volume of entrapped air (7). An enclosure is formed above the photovoltaic module (4) by a sheet of transparent material in the form of a pane of glass (8) located in a plane above and substantially parallel to the plane of the photovoltaic cells. The pane of glass is sealed to the roofing material (2) by sealing to the enclosure sides (19) which are sealed to the roofing material.

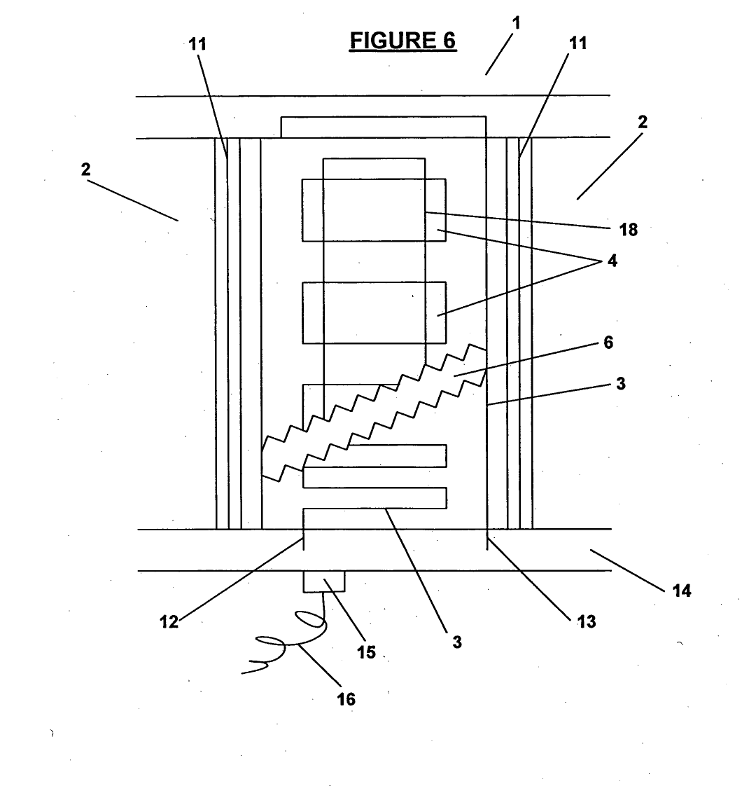

FIG. 5 shows a cross-sectional view of another energy conversion device as described above including an insulating layer (9) attached to the side (10) of the roofing material (2) opposite the surface (5) to which the convection plate (6) or photovoltaic modules (4) are bonded. The use of an insulating layer in this way enhances the efficiency of the solar collector component of the energy conversion device by preventing heat loss from the underside (10) of the roofing material (2). Conversely this provides the further advantage of reducing the heating load onto the building due to heat transfer through the roof.

FIG. 6 shows a plan view of an energy conversion device (1) according to the present invention on a standard roofing material in the form of a long run steel panel configured as a section of a standing seam roof. The zig-zag lines represent cutaway sections in order to illustrate the various layers of the device.

In this embodiment the energy conversion device (1) consists of a roofing material (2) formed as a sealed ridge configuration, having ridges (11). An open channel (3) is formed into the roofing material (2) in the planar region between the ridges (11).

The open channel (3) forms an open loop extending over substantially the length of the roof panel with the open ends of the loop (12 and 13) at the same end of the panel. In other embodiments the channel (3) is linear, extending substantially the length of the roofing panel.

A convection plate (6) is bonded to the roofing material (2) so as to cover the open channel (3), forming a continuous covered channel through which liquid can flow from a fluid inlet (12) to a fluid outlet (13).

FIG. 6 shows an embodiment in which a manifold (14) is used to connect the fluid flow to the fluid inlet (12) and the fluid outlet (13) (details of connection within the manifold are not shown in this schematic representation). The manifold (14) shown in FIG. 6 is at the lower edge of the roofing material. This represents just one of many possible configurations for the manifold (14) fluid inlet (12) and outlet (13).

Photovoltaic modules (4) are bonded onto the upper surface of the convection plate (6). A wire (18) connects the photovoltaic modules (4) to an electrical connection (15). The electricity produced by the photovoltaic modules is removed through the cable (16).

Aspects of the present invention have been described by way of example only and it should be appreciated that modifications and additions may be made thereto without departing from the scope thereof as defined in the appended claims.

1. An energy conversion device including
a roofing material, the surface of which is configured to include a trough between two adjacent crests, the trough having sides and a substantially planar base, and
at least one photovoltaic module,
characterised in that
the planar base is configured as one or more open channels over which the photovoltaic module is bonded directly or indirectly to the roofing material so as to form at least one covered channel through which fluid can flow.

2. An energy conversion device as claimed in claim 1 wherein the roofing material is a standard roofing product.

3. An energy conversion device as claimed in claim 1 wherein the roofing material is a long run metal panel.

4. An energy conversion device as claimed in claim 1 wherein the roofing material is configured as a standing seam roof.

5. An energy conversion device as claimed in claim 1 wherein the roofing material is configured as a trough sheet roof.

6. An energy conversion device as claimed in claim 1 wherein the open channel is formed during production of the roofing material.

7. An energy conversion device as claimed in claim 1 wherein the energy conversion device includes a convection plate.

8. An energy conversion device as claimed in claim 1 wherein the open channel extends substantially the length of the roofing material.

9. An energy conversion device as claimed in claim 1 which includes an entrapped air gap above the photovoltaic module.

10. An energy conversion device as claimed in claim 9 wherein the air gap is formed by a sheet of transparent material located in a plane above and substantially parallel to the plane of the photovoltaic module.

11. An energy conversion device as claimed in claim 10 wherein the edges of the transparent material are sealed to the roofing material.

12. An energy conversion device as claimed in claim 10 wherein the transparent material is glass.

13. An energy conversion device as claimed in claim 10 wherein the transparent material is a plastics material.

14. An energy conversion device as claimed in claim 9 wherein the air gap is formed by a honeycomb module material.

15. An energy conversion device as claimed in claim 1 wherein a layer of insulating material is bonded to a surface of the roofing material opposite that containing the open channel.

16. A method of forming an energy conversion device, the energy conversion device including a roofing material, the surface of which is configured to include a trough between two adjacent crests, the trough having sides and a substantially planar base, the base being further configured as one or more open channels
characterised by the step of
a) bonding one or more photovoltaic modules directly or indirectly onto the roofing material over the open channel(s) in the base so as to form at least one covered channel through which fluid can flow.

17. A method of forming an energy conversion device as claimed in claim 16
including the additional steps of
b) bonding the photovoltaic module to a first side of a convection plate, and
c) bonding a second side of the convection plate to the roofing material over the open channel(s) in the base so as to form at least one covered channel through which fluid can flow.

18. A method for producing an energy conversion device as claimed in claim 16 including the additional steps of
d) bonding a first side of a convection plate to the roofing material over the open channel(s) in the base so as to form at least one covered channel through which fluid can flow, and
e) bonding a photovoltaic module to a second side of the convection plate.

19. A method for producing an energy conversion device as claimed in claim 16 including the additional step of
d) removing heat from the energy conversion device by passing heat transfer liquid through the at least one covered channels.

20. (canceled)

21. (canceled)
